(19) United States
(12) Patent Application Publication
(10) Pub. No.: US 2024/0387755 A1
(43) Pub. Date: Nov. 21, 2024

(54) PACKAGING STRUCTURE FOR ELECTRONIC DEVICES

(71) Applicant: JCET GROUP CO., LTD., Wuxi (CN)

(72) Inventors: Xianfang YANG, Wuxi (CN); Qi ZHU, Wuxi (CN)

(21) Appl. No.: 18/614,194

(22) Filed: Mar. 22, 2024

(30) Foreign Application Priority Data
May 16, 2023 (CN) 202310550398.5

(51) Int. Cl. H01L 31/0203; H01L 33/48; H01L 33/52

(52) U.S. Cl. CPC H01L 31/0203; H01L 33/483; H01L 33/52

(57) ABSTRACT

The present disclosure pertains to a packaging structure for electronic devices, which comprises: a substrate and an optical device fixed to the substrate, an upper surface of the optical device has an optical region for receiving and/or transmitting light signals; an outer cover hermetically connected to the upper surface of the optical device and surrounding the optical region, which has an opening; and a transparent inner cover disposed inside the opening and sealing the opening, the upper surface of the optical device, the outer cover and the transparent inner cover are sealed to form a cavity, and a light signal path between the optical region and the exterior of the packaging structure passes through the opening and the transparent inner cover. The present disclosure provides a small cavity packaging structure, which maintains the sealing integrity of the cavity even when the air inside the cavity expands due to heating.

### CROSS-REFERENCE TO RELATED APPLICATION

This application claims priority under 35 U.S.C. § 119 to Chinese Patent Application No. CN202310550398.5, filed on May 16, 2023, the entire content of which is incorporated herein by reference.

### TECHNICAL FIELD

The present disclosure pertains to the field of electronic components packaging, particularly to a packaging structure for electronic devices.

### BACKGROUND

In the prior art, large cavity packaging methods are often used in packaging structures containing optical devices. FIG. 1 illustrates a schematic diagram of a large cavity packaging structure in the prior art, using Ball Grid Array (BGA) as an example. The BGA packaging substrate shown in FIG. 1 is soldered with an optical device, other chips, resistors/capacitors, and other electronic components. The upper surface of the optical device has an optical region. The optical device is connected to the substrate pad via wire binding, and an opaque outer cover is fixed to an upper surface of the substrate to seal the optical device and other components above the substrate within a cavity inside the outer cover. The upper part of the outer cover has an opening, and a transparent glass plate is fixed to the outer side the opening of the outer cover through adhesive. External light can be incident on the optical region of the optical device through the transparent glass plate.

However, electronic components often generate heat during operation. Using these large cavity packaging methods, the cavity contains a large amount of air. When the air expands due to heating, it is easy for the adhesive at the connection between the transparent glass plate and the outer cover to be broken open, which destroys the sealing of the packaging structure and results in air leakage and water ingress. This not only affects the refractive index, reduces the quality and stability of light signal transmission, but may also damage the electronic components within the packaging structure or shorten their lifespan, thus affecting the reliability of the product.

### SUMMARY

To address the aforementioned technical problems, the objective of the present disclosure is to provide a new packaging structure to solve the problem in the prior art that the large cavity packaging structure is easily damaged.

The present disclosure provides a packaging structure for electronic devices, which includes: a substrate and an optical device fixed to the substrate, an upper surface of the optical device has an optical region for receiving and/or transmitting light signals; an outer cover hermetically connected to the upper surface of the optical device and surrounding the optical region, the outer cover has an opening; and a transparent inner cover disposed inside the opening and sealing the opening, the upper surface of the optical device, the outer cover and the transparent inner cover are sealed to form a cavity, a light signal path between the optical region and the exterior of the packaging structure passes through the opening and the transparent inner cover.

In some embodiments, the upper surface of the optical device has an annular groove, the annular groove is located outside the optical region, and a bottom of the outer cover is inserted in the annular groove and is hermetically connected to the optical device through a binding material.

In some embodiments, the annular groove includes a first annular groove and a second annular groove, the first annular groove is arranged outside the second annular groove, and the bottom of the outer cover is inserted in the second annular groove.

In some embodiments, the annular groove further includes a third annular groove, and the second annular groove is arranged outside the third annular groove.

In some embodiments, the annular groove includes a second annular groove and a third annular groove, the second annular groove is arranged outside the third annular groove, and a bottom of the outer cover is inserted in the second annular groove.

In some embodiments, an outer wall of the outer cover is provided with a protruding structure, the protruding structure can be bonded integrally with an insulating packaging material.

In some embodiments, the protruding structure is an annular protrusion surrounding the outer wall of the outer cover.

In some embodiments, the protruding structure has a sloping shape with a low inside and a high outside or a high inside and a low outside.

In some embodiments, an area of the opening is larger than an area of the optical region.

In some embodiments, the outer cover is made of metal material.

In some embodiments, the packaging structure for electronic devices further includes an insulating packaging layer, and the outer cover is packaged in the insulating packaging layer with the opening being exposed.

The small cavity packaging structure adopted in the present disclosure has the following advantages:

(1) The cavity is relatively small, and there is less air inside, so even if the air inside the cavity expands due to heating, it is less likely to damage the packaging structure.

(2) The transparent inner cover is positioned inside the opening of the outer cover, which further avoids the risk of the air in the cavity being heated and expanded to push it open, thus destroying the sealing of the cavity.

### BRIEF DESCRIPTION OF THE DRAWINGS

FIG. 1 illustrates a schematic diagram of a large cavity packaging structure in the prior art;

FIG. 2 illustrates a schematic diagram of a packaging structure 1 according to an embodiment of the present disclosure;

FIG. 3A illustrates a top view of the optical device 20 in FIG. 2;

FIG. 3B illustrates a sectional view along direction A-A in FIG. 3A;

FIG. 4 illustrates a schematic diagram of a packaging structure 1 according to another embodiment of the present disclosure;

FIG. 5A illustrates a top view of the optical device 20 in FIG. 4;

FIG. 5B illustrates a sectional view along direction A-A in FIG. 5A.

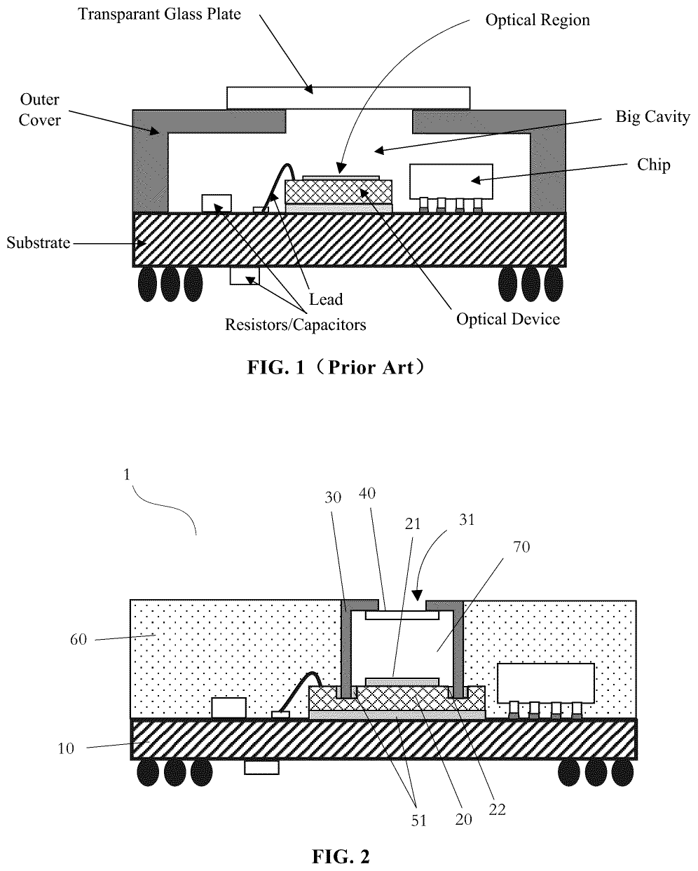

### DETAILED DESCRIPTION OF THE EMBODIMENTS

The present invention will be described in detail below with reference to specific embodiments. The following embodiments will help those skilled in the art to further understand the present invention but are not intended to limit the present invention in any form. It should be noted that, for those of ordinary skill in the art, several modifications and improvements can be made without departing from the concept of the present invention. These all belong to the protection scope of the present invention.

FIG. 2 illustrates a schematic diagram of a packaging structure 1 of an electronic device according to an embodiment of the present disclosure. As shown in FIG. 2, the packaging structure 1 includes a substrate 10, an optical device 20, an outer cover 30 and a transparent inner cover 40.

The substrate 10 is a carrier of the electronic components in the packaging structure 1 and provides electrical connections for the electronic components. According to practical needs, the shape of the upper surface of the substrate 10 can be various shapes such as circular, rectangular, or elliptical, and the substrate 10 can be made of plastic, ceramic, or other materials.

The optical device 20 is fixedly connected to the substrate 10, and can be connected using binding materials such as adhesive or sintering materials, like epoxy resin adhesive. In some embodiments, the optical device 20 may be fixedly connected to the substrate 10 by using sintering material 51 such as sintered silver or sintered copper to enhance its firmness. The upper surface of the optical device 20 has an optical region 21. In this disclosure, the optical region 21 can be any parts that can emit and/or receive light signals. The light carrying the light signal can be visible or invisible, with corresponding wavelength ranging from 10 nm to 1 mm.

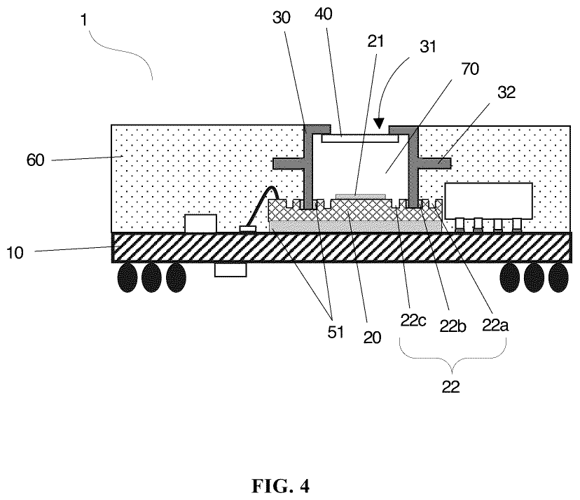

The outer cover 30 is hermetically connected to the upper surface of the optical device 20 and surrounds the optical region 21, and the outer cover 30 has an opening 31. External light signals may be incident on the optical region 21 through the opening 31, or light signals emitted from the optical region 21 may be irradiated to the outside through the opening 31. The opening 31 can be located at the top of the outer cover 30, as shown in FIGS. 2 and 4. However, in other embodiments, the opening 31 can also be located at other positions of the outer cover 30 as needed, such as the side of the outer cover 30, as long as light signals can be incident on the optical region 21 or emitted from the optical region 21 to the outside.

The outer cover 30 can be made of various materials with certain rigidity. In some embodiments, the outer cover 30 is made of metal materials to achieve good effects of electromagnetic shielding and heat dissipation.

In some embodiments, the outer cover 30 and the upper surface of the optical device 20 are hermetically connected using binding materials such as adhesive or sintering materials, etc.

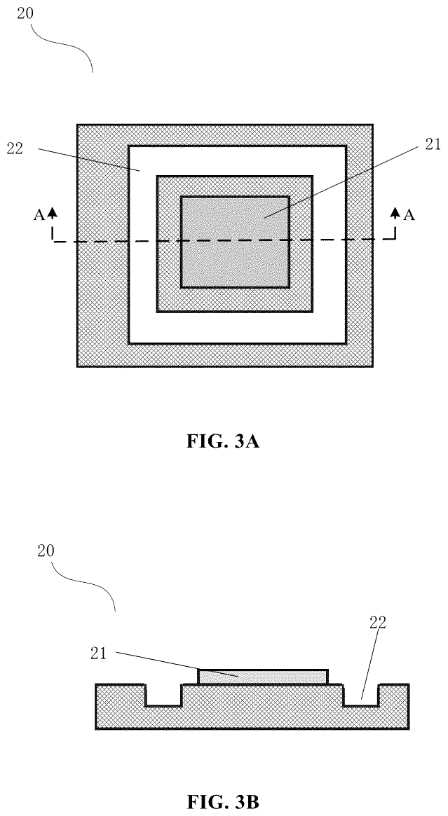

In some embodiments, in order to achieve a stronger connection between the outer cover 30 and the upper surface of the optical device 20, an annular groove 22 can be provided outside the optical region 21 on the upper surface of the optical device 20, as shown in FIGS. 3A and 3B. Among them, FIG. 3A illustrates a top view of the optical device 20 in FIG. 2, and FIG. 3B illustrates a sectional view along the direction A-A in FIG. 3A. Referring to FIG. 2, the bottom of the outer cover 30 is inserted in the annular groove 22, and the sintering material 51 is sintered into the annular groove 22 through a sintering process, thereby achieving a securely sealed connection with the optical device 20. The sintering material 51 can be of various types suitable for sintering process, such as sintered silver or sintered copper and the like. To ensure the sealing performance of the connection between the outer cover 30 and the upper surface of the optical device 20, the sintering material 51 should fill the entire groove 22 as much as possible. It should be noted that the top view shape of the annular groove 22 should have a shape that matches the bottom of the outer cover 30. Although the example of the groove 22 shown in FIG. 3A is a square annular shape, this is merely illustrative. Those skilled in the art can set the annular groove 22 into other shapes matching the bottom of the outer cover 30 according to specific requirements.

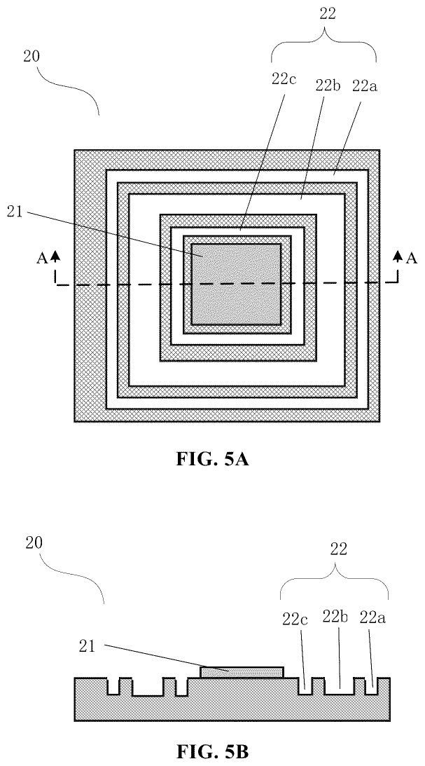

In some embodiments, in order to prevent the adhesive or sintering materials 51 from contaminating other areas of the optical device 20, two or more annular grooves 22 may be provided outside the optical region 21. FIG. 4 illustrates a schematic diagram of a packaging structure 1 according to another embodiment of the present disclosure. FIG. 5A illustrates a top view of the optical device 20 in FIG. 4. FIG. 5B illustrates a sectional view along direction A-A in FIG. 5A. As shown in FIGS. 5A and 5B, in some embodiments, the number of annular grooves 22 is at least two, including a first annular groove 22a and a second annular groove 22b, both of which are arranged outside the optical region 21. The first annular groove 22a is arranged outside the second annular groove 22b. In some embodiments, the annular groove 22 includes a second annular groove 22b and a third annular groove 22c, both of which are arranged outside the optical region 21. The second annular groove 22b is arranged outside the third annular groove 22c. In some other embodiments, the number of annular grooves 22 is at least three, including a first annular groove 22a, a second annular groove 22b and a third annular groove 22c. For the aforementioned embodiment, referring to FIG. 4, the bottom of the outer cover 30 is inserted in the second annular groove 22b, and the sintering material 51 is sintered into the second annular groove 22b through a sintering process. In this way, during the sintering process, even if the sintering material 51 may overflow out of the second annular groove 22b, the first annular groove 22a and/or the third annular groove 22c on both sides thereof can accommodate the overflowed sintering material 51 and prevent it from spreading further and contaminating other areas.

The transparent inner cover 40, which is made of transparent material, is disposed inside the opening 31 and seals the opening 31, as shown in FIGS. 2 and 4. The transparent inner cover 40 can be hermetically connected to the inner side of the opening 31 of the outer cover 30 by adhesive or other means. Since the transparent inner cover 40 is disposed inside the opening 31, even if the air inside the cavity enclosed by the transparent inner cover 40, the outer cover 30 and the upper surface of the optical device 20 expands due to heating, it cannot break the seal connection between the transparent inner cover 40 and the outer cover 30, thereby greatly improving product reliability.

The light signal path between the optical region 21 and the exterior of the packaging structure 1 passes through the opening 31 and the transparent inner cover 40. In some embodiments, the area of the opening 31 is larger than that of the optical region 21, which allows the optical region 21 to receive a wider angle range of external incident light signals, thereby enhancing the adaptability of the product and making more efficient use of the optical region 21.

In one or more embodiments, as shown in FIG. 2, the packaging structure 1 of the electronic device further includes an insulating packaging layer 60. The outer cover 30 is packaged in the insulating packaging layer 60 and exposes the opening 31, so as to form a light signal path between the optical region 21 and the exterior of the packaging structure 1. The upper surface of the optical device 20, the outer cover 30 and the transparent inner cover 40 are sealed together to form a cavity 70. Other components such as other chips, resistors/capacitors, etc., are located outside the cavity 70. In this way, the components above the substrate 10 and outside the outer cover 30 are all packaged in the insulating packaging layer 60, providing insulation, dustproof, waterproof, anti-oxidation, fixation and the like. The packaging material can be plastics, epoxy resins, polysulfides, polyurethanes, silicone, etc.

Additionally, in some embodiments, to better secure the outer cover 30 within the insulating packaging layer 60, as shown in FIG. 4, a protruding structure 32 can be provided on the outer wall of the outer cover 30. The protruding structure 32 is inserted in the insulating packaging layer 60 to increase the bonding force between the outer cover 30 and the insulating packaging layer 60, thus ensuring a more stable integration of the two. At the same time, the fixing effect of the insulating packaging layer 60 can also be utilized to enhance the sealed connection between the outer cover 30 and the upper surface of the optical device 20, further preventing the detachment of the outer cover 30 from the upper surface of the optical device 20. In some embodiments, the protruding structure 32 is an annular protrusion surrounding the outer wall of the outer cover 30, further increasing the bonding force between the outer cover 30 and the insulating packaging layer 60. To obtain better structural strength, in some embodiments, the protruding structure 32 and the outer cover 30 are integrally formed. In the embodiment shown in FIG. 4, the outer wall of the outer cover 30 is perpendicular to the upper surface of the substrate 10, and the protruding structure 32 is an annular surface perpendicular to the outer wall of the outer cover 30 and parallel to the upper surface of the substrate 10. In some other embodiments, the protruding structure may also be non-parallel to the upper surface of the substrate, such as the protruding structure 32 being a sloping shape with low inside and high outside or high inside and a low outside. This implies that the portion of the protruding structure 32 where it connects to the outer cover 30 is either lower or higher than the portion away from the outer cover 30. This can better enhance the adhesion between the outer cover and the insulating packaging layer, while also strengthening the structural strength of the outer cover itself to prevent the protruding structure 32 from breaking at the root. In some embodiments, the number of protruding structures 32 may be multiple to further enhance the bonding force between the outer cover 30 and the insulating packaging layer 60.

It should be pointed out that although FIGS. 2 and 4 take BGA packaging as an example for explanation, the present invention is not limited to BGA packaging and can be applied to any situation where optical devices need to be packaged.

The present disclosure uses a small cavity packaging structure and arranges the outer cover on the upper surface of the optical device to make the volume of the cavity inside the outer cover as small as possible, thereby reducing the volume of the outer cover material to reduce packaging costs. Furthermore, by arranging a transparent inner cover inside the opening of the outer cover, the risk of the air in the inner cavity of the outer cover being heated and expanding and then rupturing the transparent inner cover can be avoid in the present disclosure. In addition, the present disclosure achieves a secure connection between the outer cover and the upper surface of the optical device by setting a groove on the upper surface of the optical device and sintering the bottom of the outer cover into the groove through a sintering process. With the above technical solutions, the problem of poor airtightness caused by large cavity packaging in the prior art can be effectively addressed.

Those of ordinary skill in the art can understand and implement other modifications to the disclosed embodiments by reading the specification, the disclosure, the drawings, and the appended claims. In the claims, the term “comprises” does not exclude other elements or steps, and the terms “a” or “an” do not exclude plural. In practical implementation of this application, one part may perform the functions of multiple technical features cited in the claims. Any referential signs in the claims shall not be construed as limiting the scope.

What is claimed is:

1. A packaging structure for electronic devices, comprising:
a substrate;
an optical device fixed to the substrate, an upper surface of the optical device has an optical region for receiving and/or transmitting light signals;
an outer cover hermetically connected to the upper surface of the optical device and surrounding the optical region, the outer cover has an opening; and
a transparent inner cover disposed inside the opening and sealing the opening, the upper surface of the optical device, the outer cover and the transparent inner cover are sealed to form a cavity, a light signal path between the optical region and the exterior of the packaging structure passes through the opening and the transparent inner cover.

2. The packaging structure of claim 1, wherein the upper surface of the optical device has an annular groove, the annular groove is located outside the optical region, and a bottom of the outer cover is inserted in the annular groove and is hermetically connected to the optical device through a binding material.

3. The packaging structure of claim 2, wherein the annular groove comprises a first annular groove and a second annular groove, the first annular groove is arranged outside the second annular groove, and the bottom of the outer cover is inserted in the second annular groove.

4. The packaging structure of claim 3, wherein the annular groove further comprises a third annular groove, and the second annular groove is arranged outside the third annular groove.

5. The packaging structure of claim 2, wherein the annular groove comprises a second annular groove and a third annular groove, the second annular groove is arranged outside the third annular groove, and a bottom of the outer cover is inserted in the second annular groove.

6. The packaging structure of claim 1, wherein an outer wall of the outer cover is provided with a protruding structure, the protruding structure can be bonded integrally with an insulating packaging material.

7. The packaging structure of claim 6, wherein the protruding structure is an annular protrusion surrounding the outer wall of the outer cover.

8. The packaging structure of claim 6, wherein the protruding structure is a sloping shape with a low inside and a high outside or a high inside and a low outside.

9. The packaging structure of claim 1, wherein an area of the opening is larger than an area of the optical region.

10. The packaging structure of claim 1, wherein the outer cover is made of metal material.

11. The packaging structure of claim 1, wherein the packaging structure for electronic devices further comprises an insulating packaging layer, and the outer cover is packaged in the insulating packaging layer with the opening being exposed.
